(19) United States
(12) Patent Application Publication
(10) Pub. No.: US 2007/0254093 A1
(43) Pub. Date: Nov. 1, 2007

(54) MOCVD reactor with concentration-monitor feedback

(75) Inventors: Sandeep Nijhawan, Los Altos, CA (US); Lori Washington, Union City, CA (US); Jacob Smith, Santa Clara, CA (US); Garry Kwong, San Jose, CA (US); David Bour, Cupertino, CA (US); David Eaglesham, Livermore, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/411,667

(22) Filed: Apr. 26, 2006

(51) Int. Cl. C23C 16/52; C23C 16/00; B05C 11/00

(52) U.S. Cl. 427/8; 427/255.28; 118/688; 118/715

(57) ABSTRACT

Methods and systems permit fabricating structures using liquid sources without active temperature control. A liquid or solid source of the precursor is provided in a bubbler. A carrier gas source is flowed into the source to generate a flow of precursor vapor carried by the carrier gas. A relative concentration of the precursor vapor to the carrier gas of the flow is measured. A mass flow rate of the precursor in the flow is determined from the measured relative concentration. A flow rate of the carrier gas into the source is changed to maintain the mass flow rate at a defined value or within a defined range.

### CROSS-REFERENCE TO RELATED APPLICATION

This application is related to concurrently filed, commonly assigned U.S. patent application Ser. No. ______, entitled “MOCVD REACTOR WITHOUT METALORGANIC-SOURCE TEMPERATURE CONTROL,” by Sandeep Nijhawan (Attorney Docket No. A10809/T67800), the entire disclosure of which is incorporated herein by reference for all purposes.

### BACKGROUND OF THE INVENTION

The history of light-emitting diodes (“LEDs”) is sometimes characterized as a “crawl up the spectrum.” This is because the first commercial LEDs produced light in the infrared portion of the spectrum, followed by the development of red LEDs that used GaAsP on a GaAs substrate. This was, in turn, followed by the use of GaP LEDs with improved efficiency that permitted the production of both brighter red LEDs and orange LEDs. Refinements in the use of GaP then permitted the development of green LEDs, with dual GaP chips (one in red and one in green) permitting the generation of yellow light. Further improvements in efficiency in this portion of the spectrum were later enabled through the use of GaAlAsP and InGaAlP materials.

This evolution towards the production of LEDs that provide light at progressively shorter wavelengths has generally been desirable not only for its ability to provide broad spectral coverage but because diode production of short-wavelength light may improve the information storage capacity of optical devices like CD-ROMs. The production of LEDs in the blue, violet, and ultraviolet portions of the spectrum was largely enabled by the development of nitride-based LEDs, particularly through the use of GaN. While some modestly successful efforts had previously been made in the production of blue LEDs using SiC materials, such devices suffered from poor luminescence as a consequence of the fact that their electronic structure has an indirect bandgap.

While the feasibility of using GaN to create photoluminescence in the blue region of the spectrum has been known for decades, there were numerous barriers that impeded their practical fabrication. These included the lack of a suitable substrate on which to grow the GaN structures, generally high thermal requirements for growing GaN that resulted in various thermal-convection problems, and a variety of difficulties in efficient p-doping such materials. The use of sapphire as a substrate was not completely satisfactory because it provides approximately a 15% lattice mismatch with the GaN. Progress has subsequently been made in addressing many aspects of these barriers. For example, the use of a buffer layer of AlN or GaN formed from a metalorganic vapor has been found effective in accommodating the lattice mismatch. Further refinements in the production of Ga—N-based structures has included the use of AlGaN materials to form heterojunctions with GaN and particularly the use of InGaN, which causes the creation of defects that act as quantum wells to emit light efficiently at short wavelengths. Indium-rich regions have a smaller bandgap than surrounding material, and may be distributed throughout the material to provide efficient emission centers.

While some improvements have thus been made in the manufacture of such compound nitride semiconductor devices, it is widely recognized that a number of deficiencies yet exist in current manufacturing processes. Moreover, the high utility of devices that generate light at such wavelengths has caused the production of such devices to be an area of intense interest and activity. In view of these considerations, there is a general need in the art for improved methods and systems for fabricating compound nitride semiconductor devices.

### BRIEF SUMMARY OF THE INVENTION

Embodiments of the invention provide methods and systems for fabricating structures using liquid sources without active temperature control. In some embodiments, methods provide a flow of a precursor to a processing chamber for use in substrate processing. A liquid or solid source of the precursor is provided in a bubbler. A carrier gas source is flowed into the source to generate a flow of precursor vapor carried by the carrier gas. A relative concentration of the precursor vapor to the carrier gas of the flow is measured. A mass flow rate of the precursor in the flow is determined from the measured relative concentration. A flow rate of the carrier gas into the source is changed to maintain the mass flow rate at a defined value or within a defined range.

In some embodiments, a total pressure of the bubbler may be regulated with a back-pressure controller. The total pressure of the bubbler may sometimes be changed with the back-pressure controller to maintain the mass flow rate at the defined value or within the defined range.

In certain embodiments, a flow of a push gas is added into the flow to increase a total flow rate of the flow. In embodiments where the source comprises a group-III element, the push gas may comprise H₂ and/or N₂. In other instances, the source comprises a group-III element and the carrier gas comprises H₂ and/or N₂.

The concentration of the precursor vapor to the carrier gas may be measured by measuring a sound speed of the flow, from which the concentration may be determined. The source might not be subjected to active temperature control, in which case the flow may be heated to prevent condensation of the precursor vapor out of the flow.

These methods may be implemented with a precursor-delivery system that includes a bubbler and a liquid or solid source of the precursor disposed in the bubbler. A carrier-gas source is fluidicly coupled with the bubbler. A carrier-gas mass-flow controller is fluidicly coupled with the carrier-gas source to control a carrier-gas flow of the carrier-gas source into the source to generate a vapor flow of precursor vapor carried by the carrier gas. A concentration monitor is fluidicly coupled with the bubbler to measure a relative concentration of the precursor vapor to the carrier gas of the vapor flow. The concentration monitor is in electrical communication with the carrier-gas mass-flow controller and has instructions to determine a mass flow rate of the precursor in the vapor flow from the measured relative concentration. This may be used to change a flow rate of the carrier-gas flow to maintain the mass-flow rate at a defined value or within a defined range.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 provides a schematic illustration of a structure of a GaN-based LED;

FIG. 2 is a simplified representation of an exemplary CVD apparatus that may be used in implementing certain embodiments of the invention;

FIG. 3 provides a schematic illustration of a direct-liquid-injection structure used in some embodiments with the CVD apparatus of FIG. 2;

FIG. 4 is a flow diagram summarizing methods of fabricating a compound nitride semiconductor structure using direct liquid injection;

FIGS. 5A-5D illustrate the use direct mass-flow metering of metalorganic vapor with the CVD apparatus of FIG. 2; and

FIG. 6 is a flow diagram summarizing methods of direct mass-flow metering according to embodiments of the invention.

### DETAILED DESCRIPTION OF THE INVENTION

One class of techniques for deposition of group-III nitride structures is metalorganic chemical vapor deposition (“MOCVD”). Such techniques achieve deposition by providing flows of precursors for both the group-III element(s) and nitrogen to a processing chamber where thermal processes act to achieve growth of a III-N film. The effectiveness of the growth may depend on a wide array of different factors, notably including the rate at which precursors are flowed into the processing chamber and the environmental conditions within the processing chamber.

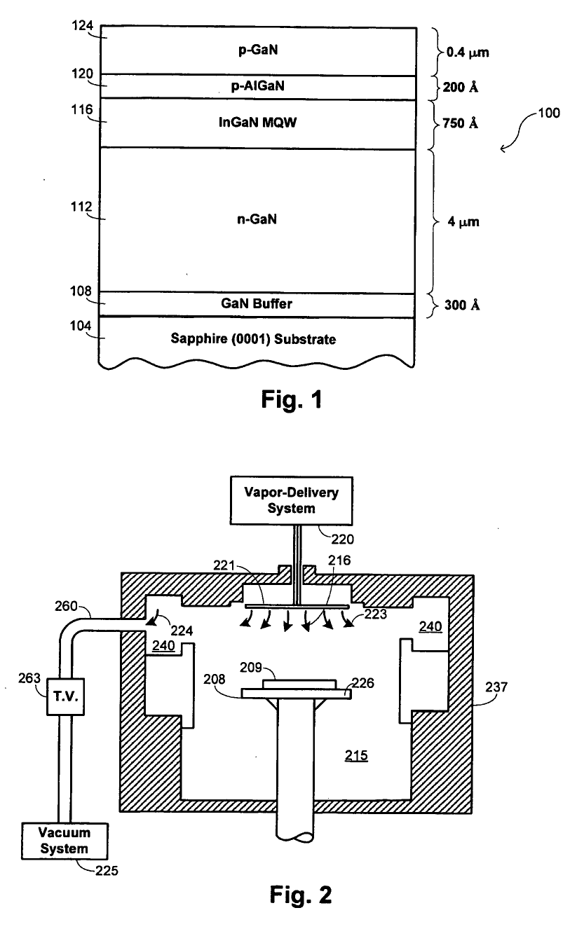

One typical nitride-based structure is illustrated in FIG. 1 as a GaN-based LED structure 100. It is fabricated over a sapphire (0001) substrate 104. An n-type GaN layer 112 is deposited over a GaN buffer layer 108 formed over the substrate. An active region of the device is embodied in a multi-quantum-well layer 116, shown in the drawing to comprise an InGaN layer. A pn junction is formed with an overlying p-type AlGaN layer 120, with a p-type GaN layer 124 acting as a contact layer.

The inclusion of different layers having different compositions illustrates how different precursors may be used in fabricating such an LED with a MOCVD process. Deposition of the layers typically follows cleaning of the substrate 104 in a processing chamber. A GaN layer may be deposited using Ga and N precursors, perhaps with a flow of a fluent gas like N₂, H₂, and/or NH₃; an InGaN layer may be deposited using Ga, N, and In precursors, perhaps with a flow of a fluent gas; and an AlGaN layer may be deposited using Ga, N, and Al precursors, also perhaps with a flow of a fluent gas. In the illustrated structure 100, the GaN buffer layer 108 has a thickness of about 300 Å, and may have been deposited at a temperature of about 550° C. Subsequent deposition of the n-GaN layer 112 is typically performed at a higher temperature, such as around 1050° C. in one embodiment. The n-GaN layer 112 is relatively thick, with deposition of a thickness on the order of 4 μm requiring about 140 minutes. The InGaN multi-quantum-well layer 116 may have a thickness of about 750 Å, which may be deposited over a period of about 40 minutes at a temperature of about 750° C. The p-AlGaN layer 120 may have a thickness of about 200 Å, which may be deposited in about five minutes at a temperature of 950° C. The thickness of the contact layer 124 that completes the structure may be about 0.4 μm in one embodiment, and may be deposited at a temperature of about 1050° C. for around 25 minutes.

An appreciable portion of the cost of a conventional III-V MOCVD reactor within which such processes may take place is the demand for recirculating-liquid constant-temperature baths. This is a consequence of the strong (exponential) dependence of the metalorganic vapor pressure with temperature, according to which the temperature of each organometallic source in conventional systems must be controlled within about ±0.1° C. A III-V MOCVD reactor may include on the order of ten metalorganic precursor bubblers, with some specific structures including 8 - 12 metalorganic precursor bubblers. In conventional systems, each of the precursor bubblers has its own constant-temperature bath. These temperature controllers are bulky, expensive, and energy-consuming. They may also be quite troublesome, especially for sources that are kept below 0° C. where condensation of moisture from air causes the temperature baths to overflow or ice up. Embodiments of the invention are accordingly directed to III-V MOCVD structures that eliminate the requirement for these temperature controllers. Using the approaches described herein, the normal metalorganic temperature control is minimized or eliminated, thereby reducing the cost, size, and energy consumption of III-V MOCVD epitaxial reactors.

2. Exemplary Substrate Processing System

FIG. 2 is a simplified diagram of an exemplary chemical vapor deposition (“CVD”) system, illustrating the basic structure of a chamber in which individual deposition steps can be performed. This system is suitable for performing thermal, sub-atmospheric CVD (“SACVD”) processes, as well as other processes, such as reflow, drive-in, cleaning, etching, deposition, and gettering processes. In some instances multiple-step processes can still be performed within an individual chamber before removal for transfer to another chamber. The major components of the system include, among others, a vacuum chamber 215 that receives process and other gases from a gas or vapor delivery system 220, a vacuum system 225, and a control system (not shown). These and other components are described in more detail below. While the drawing shows the structure of only a single chamber for purposes of illustration, it will be appreciated that multiple chambers with similar structures may be provided as part of a cluster tool, each tailored to perform different aspects of certain overall fabrication processes.

The CVD apparatus includes an enclosure assembly 237 that forms vacuum chamber 215 with a gas reaction area 216. A gas distribution structure 221 disperses reactive gases and other gases, such as purge gases, toward one or more substrates 209 held in position by a substrate support structure 208. Between gas distribution structure 221 and the substrate 209 is gas reaction area 216. Heaters 226 can be controllably moved between different positions to accommodate different deposition processes as well as for an etch or cleaning process. A center board (not shown) includes sensors for providing information on the position of the substrate.

Different structures may be used for heaters 226. For instance, some embodiments of the invention advantageously use a pair of plates in close proximity and disposed on opposite sides of the substrate support structure 208 to provide separate heating sources for the opposite sides of one or more substrates 209. Merely by way of example, the plates may comprise graphite or SiC in certain specific embodiments. In another instance, the heaters 226 include an electrically resistive heating element (not shown) enclosed in a ceramic. The ceramic protects the heating element from potentially corrosive chamber environments and allows the heater to attain temperatures up to about 1200° C. In an exemplary embodiment, all surfaces of heaters 226 exposed to vacuum chamber 215 are made of a ceramic material, such as aluminum oxide (Al₂O₃ or alumina) or aluminum nitride. In another embodiment, the heaters 226 comprises lamp heaters. Alternatively, a bare metal filament heating element, constructed of a refractory metal such as tungsten, rhenium, iridium, thorium, or their alloys, may be used to heat the substrate. Such lamp heater arrangements are able to achieve temperatures greater than 1200° C., which may be useful for certain specific applications.

Reactive and carrier gases are supplied from the gas or vapor delivery system 220 through supply lines to the gas distribution structure 221. In some instances, the supply lines may deliver gases into a gas mixing box to mix the gases before delivery to the gas distribution structure. In other instances, the supply lines may deliver gases to the gas distribution structure separately, such as in certain showerhead configurations described below. The gas or vapor delivery system 220 includes a variety of sources and appropriate supply lines to deliver a selected amount of each source to chamber 215 as would be understood by a person of skill in the art. Generally, supply lines for each of the sources include shut-off valves that can be used to automatically or manually shut-off the flow of the gas into its associated line, and mass flow controllers or other types of controllers that measure the flow of gas or liquid through the supply lines. Depending on the process run by the system, some of the sources may actually be liquid or solid sources rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art. During deposition processing, gas supplied to the gas distribution structure 221 is vented toward the substrate surface (as indicated by arrows 223), where it may be uniformly distributed radially across the substrate surface in a laminar flow.

Purging gas may be delivered into the vacuum chamber 215 from gas distribution structure 221 and/or from inlet ports or tubes (not shown) through the bottom wall of enclosure assembly 237. Purge gas introduced from the bottom of chamber 215 flows upward from the inlet port past the heater 226 and to an annular pumping channel 240. Vacuum system 225 which includes a vacuum pump (not shown), exhausts the gas (as indicated by arrows 224) through an exhaust line 260. The rate at which exhaust gases and entrained particles are drawn from the annular pumping channel 240 through the exhaust line 260 is controlled by a throttle valve system 263.

The temperature of the walls of deposition chamber 215 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during other processes, or to limit formation of deposition products on the walls of the chamber. Gas distribution manifold 221 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The system controller controls activities and operating parameters of the deposition system. The system controller may include a computer processor and a computer-readable memory coupled to the processor. The processor executes system control software, such as a computer program stored in memory. The processor operates according to system control software (program), which includes computer instructions that dictate the timing, mixture of gases, chamber pressure, chamber temperature, microwave power levels, pedestal position, and other parameters of a particular process. Control of these and other parameters is effected over control lines that communicatively couple the system controller to the heater, throttle valve, and the various valves and mass flow controllers associated with gas delivery system 220.

3. Direct Liquid Injection

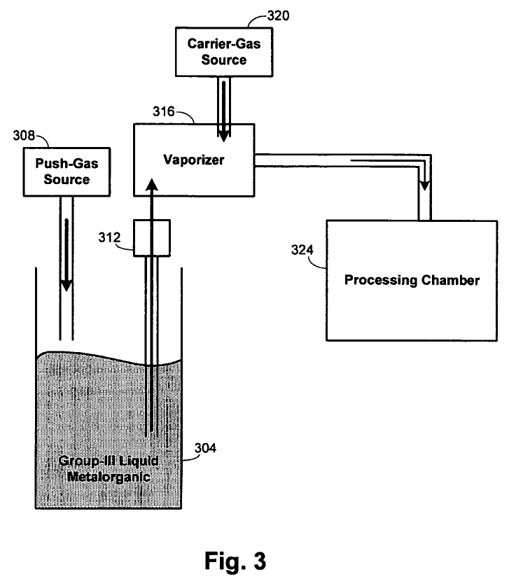

A first class of III-V MOCVD reactors that avoids the need for bubbler temperature control makes use of direct liquid injection. An illustration of a direct-liquid-injection structure that may be used is provided in FIG. 3 for a single group-III liquid metalorganic source 304. It will be understood that such a structure may be replicated one or more times for additional sources so that the gas or vapor delivery system 220 shown in FIG. 2 has access to sufficient sources to implement deposition processes for different materials. The group-III metalorganic liquid 304 is driver into a vaporizer 316 through a flow meter 312 with a push gas provided with push-gas source 308. Examples of suitable push gases include H₂ or N₂, although other push gases may be used in alternative embodiments. Metering by the flow meter 312 permits the vaporization to be of a known mass of liquid. The vaporizer 316 may also receive a carrier gas from a carrier-gas source 320, with the vaporized group-III precursor being delivered with the carrier gas to the processing chamber. Examples of suitable carrier gases also include H₂ and N₂, although alternative carrier gases may be used in alternative embodiments.

There are a number of benefits specific to III-V deposition that such a structure provides, in addition to the elimination of conventional bubbler temperature controls. For instance, the such an arrangement permits the use of very low vapor-pressure liquid metalorganic sources. Such sources are considered undesirable with conventional III-V MOCVD reactors because their conventional delivery by evaporation into a carrier gas results in a very limited growth rate. For example, trimeythlindium (“TMI”) is the most commonly used indium precursor and is favored over triethylindium (“TEI”) in conventional III-V MOCVD reactors. This preference is a consequence of the much higher vapor pressure of TMI compared with TEI at room temperature and the higher melting point of TMI compared with TEI-TMI has a melting point of 88° C. and a vapor pressure at 25° C. of 2.58 mmHg while TEI has a melting point of −32° C. and a vapor pressure at 25° C. of 0.31 mmHg. By overcoming the reliance on simple evaporation for vapor delivery, high growth rates may be achieved with TEI when direct liquid injection is used.

More generally, embodiments of the invention permit the use of group-III precursors having vapor pressures at 25° C. that are less than 2 mmHg or less than 1 mmHg in different embodiments. The vapor pressures of gallium precursors tend to be greater than those of aluminum or indium precursors, with embodiments of the invention enabling the use of gallium precursors having vapor pressures at 25° C. that are less than 100 mmHg, less than 10 mmHg, or less than 1 mmHg. The following table summarizes certain physical properties of group-III precursors whose use is enabled by embodiments of the invention and compares them with precursors used most commonly in conventional III-V MOCVD reactors (shaded regions):

TABLE I
Group-III Precursor Properties

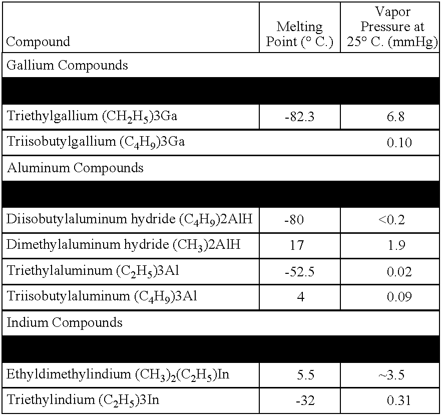

In some instances, deposited III-V films may include dopants, with embodiments of the invention further enabling the use additional dopant precursors. Merely by way of example, one precursor that may be used to provide magnesium dopants is bis(methylcyclopentadienyl)magnesium (CH₃C₅H₄)2Mg, which has a melting point of 29° C. and a vapor pressure at 25° C. of 0.35 mmHg, as contrasted with the more conventional bis(cyclopentadienyl)magnesium (C₅H₅)2Mg precursor, which has a melting point of 176° C.

In addition to enabling the use of additional precursors, the use of direct liquid injection may also provide benefits to both the MOCVD growth process and to the quality of material that is grown. For instance, in the growth of III-N films, a more active nitrogen-rich growth ambient may be achieved with direct liquid injection of efficient nitrogen precursor liquids such as hydrazine N₂H₄ or its variants dimethylhydrazine C₂H₈N₂, phenylhydrazine C₆H₈N₂, butylhydrazine, C₄H₁₂N₂, etc. (referred to herein collectively as “hydrazines”). Injection of vapor from such precursors in combination with a flow of ammonia NH₃ to the processing chamber may reduce the formation of nitrogen vacancies. The formation of nitrogen vacancies is believed by the inventors to have a generally detrimental effect on the optoelectronic properties of the III-N film that is deposited. Nitrogen vacancies in III-N films are believed to be nonradiative, a hypothesis that results from analogy with vacancies in other III-V semiconductor structures in which the group-V vacancies are known to be nonradiative. The use of direct liquid injection, particularly in combination with a gaseous nitrogen-precursor flow, results in fewer nitrogen vacancies being formed, which in turn causes the overall quantum efficiency of the deposited film to increase. The inventors anticipate that embodiments of the invention will provide more activated nitrogen for reaction and thereby increase the quantum efficiency from being on the order of 40-50% to being on the order of 80-90%. This hypothesis is consistent with observations that improved optoelectronic properties are obtained in processes performed at higher NH₃ partial pressures.

In the case of deposition of aluminum nitride layers such as AlGaN or InAlGaN, direct liquid injection allows the otherwise strong parasitic gas-phase reaction between TMA and NH₃ to be overcome. This is avoided by use of an aluminum precursor in which the bond sites normally available for TMA-NH₃ adduct formation are already satisfied.

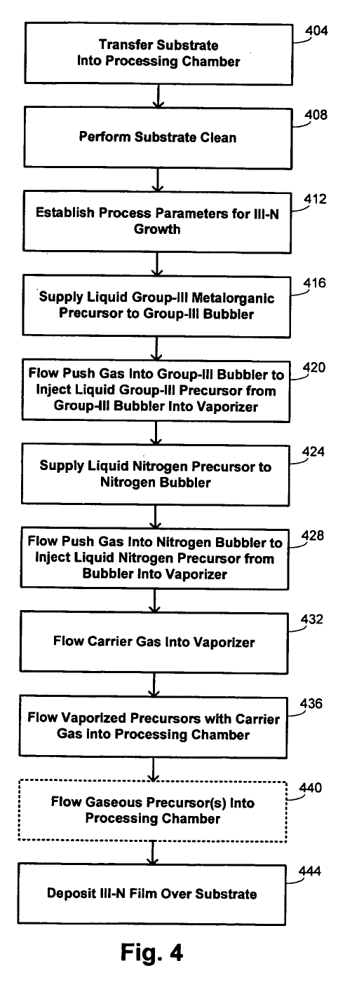

The flow diagram of FIG. 4 generally summarizes methods for fabricating a compound nitride semiconductor structure that uses direct liquid injection of liquid precursors. The method begins at block 404 with a substrate being transferred into a processing chamber. Suitable materials over which nitride structures may be fabricated include sapphire, SiC, silicon, spinel, lithium gallate, ZnO, and others. The substrate is cleaned at block 408, after which process parameters suitable for growth of a nitride layer may be established at block 412. Such process parameters may include temperature, pressure, and the like to define an environment within the processing chamber appropriate for thermal deposition of a nitride layer.

Precursors are provided to the processing chamber by supplying a liquid group-III metalorganic precursor to the a group-III bubbler at block 416. In some embodiments, the liquid group-III precursor comprises a gallium precursor having a vapor pressure at 25° C. less than 100 mmHg, less than 10 mmHg, or less than 1 mmHg. In other embodiments, the liquid group-III precursor comprises a nongallium group-III precursor having a vapor pressure at 25° C. less than 2 mmHg or less than 1 mmHg. When a plurality of group-III precursors are used, they may be supplied to a corresponding plurality of bubblers. A push gas such as H₂ and/or N₂ is flowed into the group-III bubbler at block 420 to inject liquid group-III precursor from the group-III bubbler into a vaporizer. Similarly, a liquid nitrogen precursor such as a hydrazine is supplied to a nitrogen bubbler at block 424. A push gas such as H₂ and/or N₂ is flowed into the nitrogen bubbler to inject some of the liquid nitrogen precursor from the bubbler into the vaporizer at block 428.

As indicated at block 432, a carrier gas such as H₂ and/or N₂ may be flowed into the vaporizer at block 432, permitting the vaporized precursors and carrier gas to be flowed into the processing chamber at block 436. In some embodiments, one or more additional gaseous precursors may be flowed into the processing chamber at block 440, such as in embodiments where NH₃ is flowed as a gas into the processing chamber in addition to use of a liquid nitrogen precursor. Thermal processes are used in the processing chamber, which has been prepared at block 412 to provide an environment suitable for nitride growth, to deposit the III-N film over the substrate.

While this flow diagram summarizes methods for deposition of a single layer over a substrate, it will be appreciated that the process may be repeated with different liquid precursors and/or different flow rates into the processing chamber to deposit additional layers having different compositions. Such additional depositions may be performed within the same processing chamber or may be performed in a different processing chamber adapted for more efficient growth of layers having certain desired characteristics. Further description of a cluster tool that includes multiple chambers that may be used for such multichamber processes is described in copending, commonly assigned U.S. patent application Ser. No. ______, entitled “EPITAXIAL GROWTH OF COMPOUND NITRIDE SEMICONDUCTOR STRUCTURES,” filed by Sandeep Nijhawan et al. (Attorney Docket No. A10938/T68100), the entire disclosure of which is incorporated herein by reference for all purposes.

It is noted that in addition to permitting the delivery of low vapor pressure liquid precursors, use of direct liquid injection reduces temperature control requirements. It is estimated that temperature control within a few ° C. is sufficient, as compared with the approximately ±0.1° C. that characterizes conventional approaches. In addition, direct liquid injection dos not require bubble back-pressure control and vapor delivery is independent of the liquid level in the bubbler. In some embodiments, multiple liquid-flow meters may feed into one or more injector valves.

4. Direct Mass-Flow Metering of Metalorganic Vapor

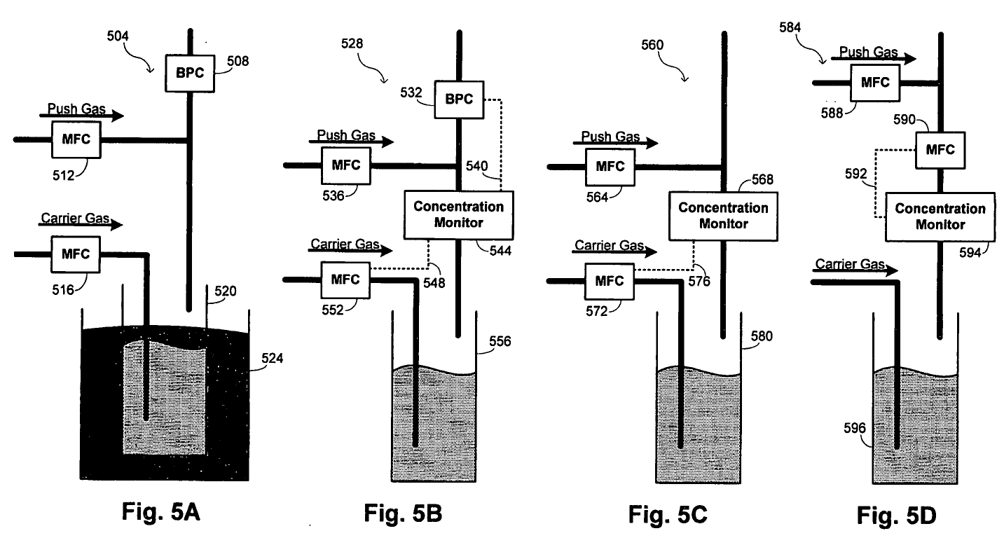

Other embodiments of the invention use direct mass-flow control to reduce or S eliminate the need for bubbler temperature control. In these embodiments, instruments capable of direct measurement of the concentration of metalorganic vapor dissolved in a carrier gas are used to provide real-time feedback control of the metalorganic vapor delivery. A number of different configurations that make use of such measurement are illustrated with FIGS. 5B-5D, each of which may be compared with FIG. 5A, which shows a conventional arrangement that makes use of temperature control.

In the conventional arrangement 504 of FIG. 5A, a bubbler 520 that holds liquid precursor is disposed within a temperature bath 524 to control the bubbler temperature and maintain the liquid precursor at temperature T. Carrier gas is flowed into the liquid precursor through a mass flow controller 516. The metalorganic vapor pressure P_{MO}^{(v)} is determined by the bubbler temperature T. The metalorganic flow f_{MO} is controlled by the metalorganic vapor pressure P_{MO}^{(v)}, the carrier-gas flow f_{carrier}, and the total bubbler pressure Pₜₒₜₐₗ. The total bubbler pressure Pₜₒₜₐₗ is determined by a back-pressure controller 508 provided downstream of the bubbler 520. For a saturated mixture, the metalorganic flow f_{MO} is thus

$${f}_{MO} = {f}_{carrier} \frac{{P}_{MO}^{( v )}}{{P}_{total} - {P}_{MO}^{( v )}} .$$

In some instances, an additional push flow is provided through mass-flow controller 512 after the bubbler 520. This increases the total flow so that the response by the back-pressure controller 508 is reasonably fast, a feature that is of greater relevance when the carrier flow is relatively small.

As shown in FIG. 5B, the temperature bath may be omitted by use of a concentration monitor. The basic flow structure with the arrangement 528 of FIG. 5B is the same as that shown in FIG. 5A: liquid or solid precursor is maintained in a bubbler 556 through which a carrier gas is flowed through mass-flow controller 552. The bubbler pressure is determined by a back-pressure controller 532 provided downstream of the bubbler, and a push flow may be provided through mass-flow controller 536 to increase total flow. The concentration monitor 544 dynamically measures the concentration of the metalorganic vapor dissolved in the carrier gas along the flow from the bubbler. While the invention is not limited to any specific structure for the concentration monitor 544, in some embodiments it performs a sound speed measurement of the flow as it passes through the monitor. The sound speed is correlated with the composition of the flow, permitting a determination of the concentration of metalorganic molecules in the flow. Monitors that implement such functionality are available commercially under the names Epison from Thomas Swan, Composer from Inficon, and Piezocon from Lorex.

The concentration monitor 544 includes communications links 548 and 540 respectively to the carrier-gas mass-flow controller 552 and/or the back-pressure controller 532. This communications links are used to provide dynamic control of the carrier flow and/or of the bubbler pressure to generate the desired metalorganic mass flow, which is a product of the concentration and flow. In this way, the ability to control the mass transport directly and dynamically compensates for any variations in temperature, pressure, or other conditions of the bubbler source. It is generally anticipated that the bubbler temperature in such embodiments will be approximately room temperature. The push flow, when included, may provide the additional function of diluting the gas mixture to avoid condensation of the metalorganic at such temperatures. In other instances, the gas lines are heated to reduce the probability of metalorganic condensation.

In another embodiment, shown in FIG. 5C, back-pressure control is also removed. The basic flow structure with this arrangement 560 is again similar to that of FIGS. 5A and 5B, with a liquid or solid precursor being maintained in a bubbler 580 through which a carrier gas is flowed through mass-flow controller 572. A push flow through mass-flow controller 564 may be included to increase total flow. Similar to FIG. 5B, a concentration monitor 568 is disposed to measure the concentration of metalorganic in the resulting flow from the bubbler dynamically and to initiate an adjustments in the flow characteristics to maintain a desired mass flow. In this embodiment, the concentration monitor 568 includes communications links 576 with the carrier-gas mass-flow controller 572 to control the carrier flow in maintaining the desired metalorganic mass flow. This embodiment has no active back-pressure control, but might use a mechanism such as a needle valve to create some back pressure.

Without active back-pressure control, the bubbler pressure floats at a value slightly above the reactor pressure. While this embodiment has the advantage of using fewer components that the embodiment shown in FIG. 5B and using a generally simpler structure, the response time for changes to the mass-flow setpoint are generally expected to be greater than in embodiments that use active back-pressure control. For example, the bubbler's head volume could be on the order of 100 cm³; if the bubbler flow is on the order of 10 sccm, the time to re-equilibrate when a change of the mass flow is instructed may be several minutes.

This response time may be significantly reduced changing the position of the carrier-gas mass flow controller. Such an arrangement is illustrated in FIG. 5D, which shows a carrier gas flowed into a bubbler 596, but with the mass-flow controller 590 downstream of the bubbler 596 and close to the concentration monitor 594. Communications links 592 between the concentration monitor 594 and the mass-flow controller 590 permit similar dynamic control over the desired mass flow of metalorganic as do the other embodiments. The arrangement 584 may also provide a push gas through mass-flow controller 588 to increase overall flow. To support flow through the downstream mass-flow controller 590, the bubbler's internal pressure is generally higher than would be used in an embodiment that has an upstream controller 572 like that shown in FIG. 5C. This limits the metalorganic vapor transport.

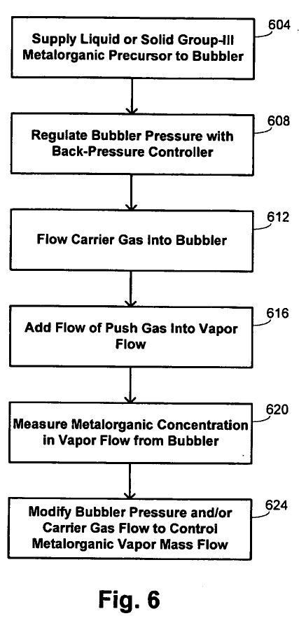

The various embodiments shown in FIGS. 5B-5D have a number of common features, some of which are noted in the following description of the flow diagram of FIG. 6, which summarizes various methods for generating metalorganic vapor for use in deposition of III-N and other structures. As indicated at block 604, a liquid or solid group-III or dopant metalorganic precursor is supplied to a bubbler. In some embodiments, the bubbler pressure is controlled with a back-pressure controller as indicated at block 608, although this is not performed in all embodiments. Carrier gas is flowed into the bubbler as indicated at block 612 and a flow of a push gas may sometimes additionally be added to the vapor flow at block 616. For deposition of III-N structures, suitable carrier and push gases include H₂ and/or N₂. At block 620, the metalorganic concentration in the vapor flow from the bubbler is measured, permitting the bubbler pressure and/or the carrier gas flow to be modified at block 624 in controlling the metalorganic vapor mass flow.

As previously noted, such methods permit greater flexibility on temperature control, and may permit the temperature control to be eliminated entirely. The mass-flow control arrangement naturally compensates for changes in the bubbler condition over the lifetime of the bubbler. The structures described may be implemented for any or all metalorganic sources in MOCVD processes, although the greatest reductions in cost, size, and total energy consumption are expected when they are implemented for all metalorganic sources.

Having fully described several embodiments of the present invention, many other equivalent or alternative methods of producing the cladding layers of the present invention will be apparent to those of skill in the art. These alternatives and equivalents are intended to be included within the scope of the invention, as defined by the following claims.

What is claimed is:

1. A method of providing a flow of a precursor to a processing chamber for use in substrate processing, the method comprising:
providing a liquid or solid source of the precursor in a bubbler;
flowing a carrier gas source into the source to generate a flow of precursor vapor carried by the carrier gas;
measuring a relative concentration of the precursor vapor to the carrier gas of the flow;
determining a mass flow rate of the precursor in the flow from the measured relative concentration; and
changing a flow rate of the carrier gas into the source to maintain the mass flow rate at a defined value or within a defined range.

2. The method recited in claim 1 further comprising regulating a total pressure of the bubbler with a back-pressure controller.

3. The method recited in claim 2 further comprising changing the total pressure of the bubbler with the back-pressure controller to maintain the mass flow rate at the defined value or within the defined range.

4. The method recited in claim 1 further comprising adding a flow of a push gas into the flow to increase a total flow rate of the flow.

5. The method recited in claim 4 wherein:
the source comprises a group-III element; and
the push gas comprises H₂ and/or N₂.

6. The method recited in claim 1 wherein measuring the concentration of the precursor vapor to the carrier gas comprises:
measuring a sound speed of the flow; and
determining the concentration from the measured sound speed.

7. The method recited in claim 1 wherein the source comprises a group-III element.

8. The method recited in claim 7 wherein the carrier gas source comprises H₂ and/or N₂.

9. The method recited in claim 1 wherein the source is not subject to active temperature control.

10. The method recited in claim 9 further comprising heating the flow to prevent condensation of the precursor vapor out of the flow.

11. A precursor-delivery system configured to introduce a precursor into a processing chamber, the precursor-delivery system comprising:
a bubbler;
a liquid or solid source of the precursor disposed in the bubbler;
a carrier-gas source fluidicly coupled with the bubbler;
a carrier-gas mass-flow controller fluidicly coupled with the carrier-gas source to control a carrier-gas flow of the carrier-gas source into the source to generate a vapor flow of precursor vapor carried by the carrier gas;
a concentration monitor fluidicly coupled with the bubbler to measure a relative concentration of the precursor vapor to the carrier gas of the vapor flow, wherein the concentration monitor is in electrical communication with the carrier-gas mass-flow controller and has instructions to determine a mass flow rate of the precursor in the vapor flow from the measured relative concentration and to change a flow rate of the carrier-gas flow to maintain the mass flow rate at a defined value or within a defined range.

12. The precursor-delivery system recited in claim 11 further comprising a back-pressure regulator fluidicly coupled with the bubbler to regulate a total pressure of the bubbler.

13. The precursor-delivery system recited in claim 12 wherein the concentration monitor is in electrical communication with the back-pressure regulator and further has instructions to change the total pressure of the bubbler with the back-pressure regulator to maintain the mass flow rate at the defined value or within the defined range.

14. The precursor-delivery system recited in claim 11 further comprising:
a push-gas source fluidicly coupled with the vapor flow; and
a push-gas mass-flow controller fluidicly coupled with the push-gas source to control a push-gas flow of the push-gas source into the vapor flow to increase a total flow rate of the vapor flow.

15. The precursor-delivery system recited in claim 14 wherein:
the source comprises a group-III element; and
the push-gas source comprises H₂ and/or N₂.

16. The precursor-delivery system recited in claim 11 wherein the concentration monitor is configured to measure and sound speed of the vapor flow and to determine the concentration from the measured sound speed.

17. The precursor-delivery system recited in claim 11 wherein the source comprises a group-III element.

18. The precursor-delivery system recited in claim 17 wherein the carrier-gas source comprises H₂ and/or N₂.

19. The precursor-delivery system recited in claim 11 wherein the source is not subject to active temperature control.

20. The precursor-delivery system recited in claim 19 wherein the vapor flow is heated to prevent condensation of the precursor vapor out of the vapor flow.
